(19) United States
(12) Patent Application Publication
(10) Pub. No.: US 2026/0076066 A1
(43) Pub. Date: Mar. 12, 2026

(54) COVER GLASS, DISPLAY DEVICE INCLUDING THE COVER GLASS AND ELECTRONIC DEVICE INCLUDING THE COVER GLASS

(71) Applicant: Samsung Display Co., Ltd., Yongin-si (KR)

(72) Inventor: Gyeongsang Park, Yongin-si (KR)

(21) Appl. No.: 19/310,318

(22) Filed: Aug. 26, 2025

(30) Foreign Application Priority Data
Sep. 10, 2024 (KR) 10-2024-0123407

(51) Int. Cl. H10K 59/80; G02B 1/14

(52) U.S. Cl. CPC H10K 59/8722; G02B 1/14

(57) ABSTRACT

A display device includes a substrate having a display area and a peripheral area, a display layer on the substrate, a first adhesive layer on the display layer, and a cover glass on the first adhesive layer, the cover glass includes a glass portion including a transparent material, a first ink layer on a first glass surface of the glass portion, the first glass surface facing (e.g., opposite to) the substrate, and the first ink layer overlapping the peripheral area, and a second ink layer on a first ink surface of the first ink layer, the first ink surface facing (e.g., opposite to) the substrate, and the second ink layer overlapping the peripheral area, where the second ink layer includes an ink portion including a shielding ink, and the second ink layer has a plurality of first areas exposing the first ink layer from the ink portion.

### CROSS-REFERENCE TO RELATED APPLICATION

The present application claims priority to and the benefit of Korean Patent Application No. 10-2024-0123407, filed on Sep. 10, 2024, in the Korean Intellectual Property Office, the entire disclosure of which is incorporated herein by reference.

### BACKGROUND

### 1. Field

One or more embodiments of the present disclosure relate to a display device, and for example, to a cover glass, a display device including the cover glass, and an electronic device including the cover glass.

### 2. Description of the Related Art

Mobile electronic devices have become ubiquitous. Recently, in addition to small electronic devices such as mobile phones, tablet personal computers (PCs) are being widely used as mobile electronic devices.

To support various functionalities, these mobile electronic devices include display devices that provide visual information, such as images or videos, to users.

With advancements in component miniaturization, the significance of display devices in electronic devices has grown. Consequently, structures that may bend from a flat state to a certain angle are being developed.

The above information disclosed in this Background section is intended to enhance understanding of the background of the disclosure and may contain information that does not constitute prior art.

### SUMMARY

Aspects of one or more embodiments of the present disclosure are directed toward a cover glass with (e.g., having) enhanced (e.g., improved) adhesion to a display panel.

Aspects of one or more embodiments of the present disclosure are directed toward a display device including a cover glass with (e.g., having) enhanced (e.g., improved) adhesion to a display panel.

Aspects of one or more embodiments of the present disclosure are directed toward an electronic device including a cover glass with (e.g., having) enhanced (e.g., improved) adhesion to a display panel.

However, these objectives and aspects are merely examples, and the problems to be addressed by the present disclosure are not limited thereto.

Additional aspects will be set forth in part in the description which follows and, in part, will be apparent from the description, or may be learned by practice of the presented embodiments of the disclosure.

According to one or more embodiments of the present disclosure, a display device includes a substrate having a display area and a peripheral area, a display layer arranged on the substrate, a first adhesive layer arranged on the display layer, and a cover glass arranged on the first adhesive layer, wherein the cover glass includes a glass portion including a transparent material, a first ink layer arranged on a first glass surface of the glass portion, the first glass surface facing the substrate, and the first ink layer overlapping the peripheral area, and a second ink layer arranged on a first ink surface of the first ink layer, the first ink surface facing the substrate, and the second ink layer overlapping the peripheral area, and the second ink layer includes an ink portion including a shielding ink, and the second ink layer has a plurality of first areas exposing the first ink layer from the ink portion.

In one or more embodiments of the present disclosure, at least a portion of the first adhesive layer may be arranged in at least one of the plurality of first areas.

In one or more embodiments of the present disclosure, the first adhesive layer may be in contact with each of the first ink layer and the ink portion.

In one or more embodiments of the present disclosure, the thickness of the first ink layer may be constant. For example, the thickness of the first ink layer is maintained at a constant level or the thickness of the first ink layer remains uniform throughout.

In one or more embodiments of the present disclosure, the ink portion may include a plurality of ink portions, wherein the plurality of ink portions may be spaced and/or apart (e.g., spaced apart or separated) from each other with the plurality of first areas arranged therebetween.

In one or more embodiments of the present disclosure, the plurality of ink portions may be arranged at equal intervals along the perimeter of the peripheral area.

In one or more embodiments of the present disclosure, the ink portion may be one piece (e.g., a single unitary piece), and the plurality of first areas may include a plurality of first openings that are spaced and/or apart (e.g., spaced apart or separated) from each other and expose the first ink layer from the ink portion.

In one or more embodiments of the present disclosure, the plurality of first openings may be arranged with each other at equal intervals along the perimeter of the peripheral area.

In one or more embodiments of the present disclosure, the plurality of first openings may be arranged in a zigzag pattern in a plan view.

In one or more embodiments of the present disclosure, at least one of the plurality of first areas may have a rectangular shape in a plan view.

According to one or more embodiments of the present disclosure, a cover glass includes a glass portion including a transparent material and having a central area and a peripheral area, a first ink layer arranged on a first glass surface of the glass portion and exposing the central area of the glass portion, and a second ink layer arranged on a first ink surface of the first ink layer, wherein the second ink layer includes an ink portion including a shielding ink, and has a plurality of first areas exposing the first ink layer from the ink portion.

In one or more embodiments of the present disclosure, the thickness of the ink portion may be the same along the perimeter of the first glass surface.

In one or more embodiments of the present disclosure, the second ink layer may include a same material as the first ink layer.

In one or more embodiments of the present disclosure, the thickness of the first ink layer may be constant.

In one or more embodiments of the present disclosure, the ink portion may include a plurality of ink portions, wherein the plurality of ink portions may be spaced and/or apart (e.g., spaced apart or separated) from each other with the plurality of first areas arranged therebetween.

In one or more embodiments of the present disclosure, the plurality of ink portions may be arranged with each other at equal intervals.

In one or more embodiments of the present disclosure, the ink portion may be one piece, and the plurality of first areas may include a plurality of first openings that are spaced and/or apart (e.g., spaced apart or separated) from each other and may expose the first ink layer from the ink portion.

In one or more embodiments of the present disclosure, the plurality of first openings may be arranged with each other at equal intervals.

In one or more embodiments of the present disclosure, the plurality of first openings may be arranged in a zigzag pattern in a plan (e.g., bottom-up) view.

In one or more embodiments of the present disclosure, at least one of the plurality of first areas may have a rectangular shape in a plan (e.g., bottom-up) view.

According to one or more embodiments of the present disclosure, an electronic device includes a cover glass including a glass portion including a transparent material and having a central area and a peripheral area, a first ink layer on a first glass surface of the glass portion in the peripheral area and exposing the central area of the glass portion, and a second ink layer on a first ink surface of the first ink layer, wherein the second ink layer includes an ink portion including a shielding ink and has a plurality of first areas exposing the first ink layer from the ink portion.

Other aspects, features, and/or principles will be clear from the details of the drawings, the claims and the details of the present disclosure.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view schematically illustrating a display device according to one or more embodiments of the present disclosure;

FIG. 2 is an equivalent circuit diagram illustrating a display element provided in one pixel of a display device and a pixel circuit connected to the pixel, according to one or more embodiments of the present disclosure;

FIG. 3 is a cross-sectional view taken along the line III-III′ of FIG. 1 and schematically illustrating a display device according to one or more embodiments of the present disclosure;

FIG. 4 is a cross-sectional view taken along the line IV-IV′ of FIG. 1 and schematically illustrating a portion of a display panel according to one or more embodiments of the present disclosure;

FIG. 5 is a plan (e.g., bottom-up) view schematically illustrating a cover glass according to one or more embodiments of the present disclosure;

FIG. 6 is a cross-sectional view taken along the line VI-VI′ of FIG. 5 and schematically illustrating a cover glass according to one or more embodiments of the present disclosure;

FIG. 7 is a plan (e.g., bottom-up) view schematically illustrating a cover glass according to one or more embodiments of the present disclosure;

FIG. 8 is a cross-sectional view taken along the line VIII-VIII′ of FIG. 7 and schematically illustrating a cover glass according to one or more embodiments of the present disclosure; and

FIG. 9 is a plan (e.g., bottom-up) view schematically illustrating a cover glass according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art.

Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, duplicative descriptions thereof may not be provided.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As the present description allows for various changes and numerous embodiments, certain embodiments will be illustrated in the drawings and described in more detail in the written description. Effects and features of the present disclosure, and methods of achieving them will be clarified with reference to one or more embodiments described below in detail with reference to the drawings. However, the disclosure is not limited to the following embodiments and may be embodied in one or more suitable forms.

Hereinafter, embodiments will be described in more detail with reference to the accompanying drawings. When describing embodiments with reference to the accompanying drawings, the same or corresponding elements are denoted by the same reference numerals and redundant descriptions thereof are omitted.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section.

Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present.

Also, sizes of elements in the drawings may be exaggerated or reduced for convenience of explanation. For example, because sizes and thicknesses of elements in the drawings may be arbitrarily illustrated for convenience of explanation, the present disclosure is not limited thereto. In the drawings, the relative sizes of elements, layers, and regions may be exaggerated for clarity.

As used herein, the terms “use,” “using,” and “used” may be considered synonymous with the terms “utilize,” “utilizing,” and “utilized,” respectively.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below.

The device may be otherwise oriented (e.g., rotated 90 degrees or at other orientations) and the spatially relative descriptors used herein should be interpreted accordingly.

In the following embodiments, the x-axis, y-axis, and z-axis are not limited to the three axes in the Cartesian coordinate system, but can be interpreted in a broad sense as including but not limited to the Cartesian coordinate system. For example, the x-axis, the y-axis, and the z-axis may be normal (e.g., perpendicular) to one another or may represent different directions that are not normal (e.g., perpendicular) to one another.

In the context of the present disclosure and unless otherwise defined, a plan view is an orthographic projection of a three-dimensional object from the position of a horizontal plane through the object. That is, it may be a top-down or bottom-up view showing the layout and spatial relationships of various elements within the object or structure. A plan view based on the z-axis direction refers to a top-down or bottom-up view of the display panel, as if looking directly down onto the surface from above or up onto the surface from below. In this context, the z-axis is the direction perpendicular or normal to the plane defined by the x-axis and y-axis directions. This refer to that in a plan view, the arrangement of sub-pixels, pads, and other components as they are laid out on the substrate may be seen without any perspective distortion.

When one or more embodiments can be implemented differently, a specific process sequence may be performed differently from the described sequence. For example, two processes described in succession may be performed substantially at the same time, or may be performed in an order opposite to that in which they are described.

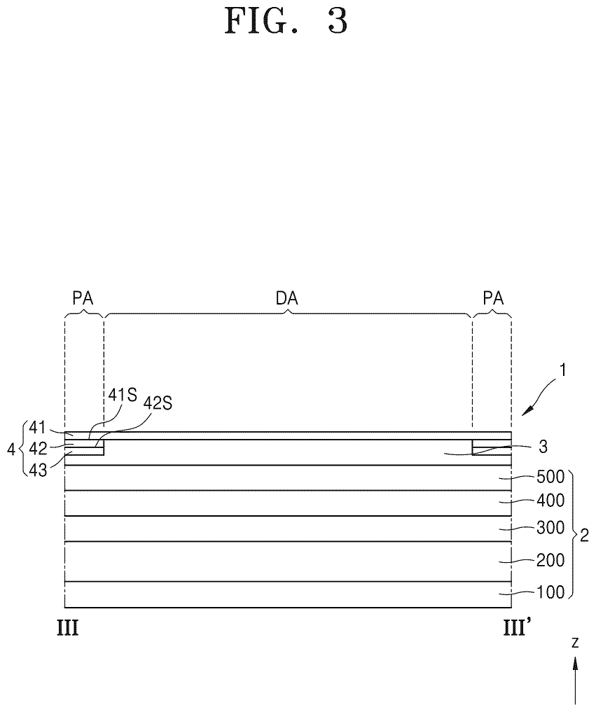

In this specification, “in a plan view” refers to a plane viewed in a direction normal (e.g., perpendicular) to a substrate (see 100 of FIG. 3). For example, “A and B are mutually spaced and/or apart (e.g., spaced apart or separated) from each other in a plan view” refers to that “A and B are mutually spaced and/or apart (e.g., spaced apart or separated) from each other when viewed in a direction normal (e.g., perpendicular) to the substrate (see 100 of FIG. 3).”

In this specification, “in a cross-sectional view” refers to a plane cut in a direction normal (e.g., perpendicular) to the substrate (see 100 of FIG. 3). For example, “A and B are mutually spaced and/or apart (e.g., spaced apart or separated) from each other in a cross-sectional view” refers to “A and B are mutually spaced and/or apart (e.g., spaced apart or separated) from each other in a plane cut in a direction normal (e.g., perpendicular) to the substrate (see 100 of FIG. 3).”

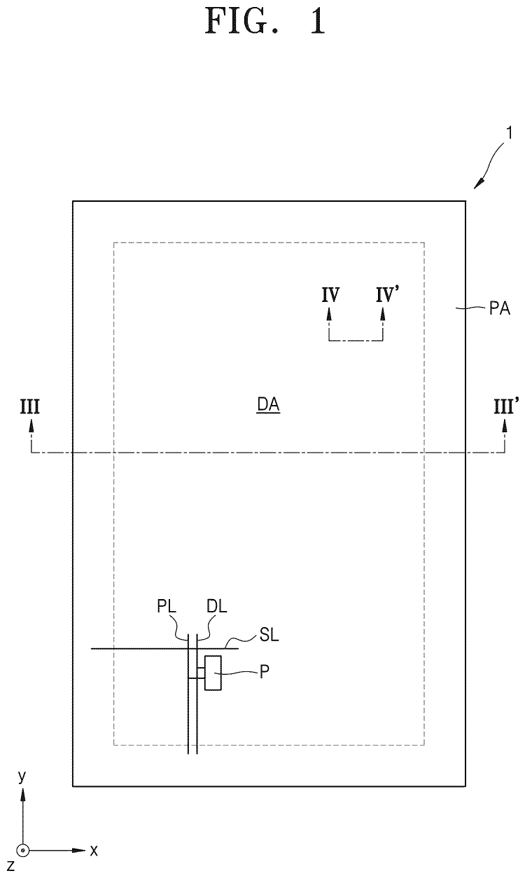

FIG. 1 is a plan view schematically illustrating a display device 1 according to one or more embodiments of the present disclosure.

Referring to FIG. 1, the display device 1 may include a display area DA and a peripheral area PA. The display device 1 may provide an image by using light emitted from a plurality of pixels P in the display area DA.

Each of the plurality of pixels P may include a display element such as an organic light-emitting diode or an inorganic light-emitting diode, and may be to emit, for example, red light, green light, blue light, and/or white light. For example, each of the plurality of pixels P may be connected to a pixel circuit including a thin-film transistor, a storage capacitor, and/or the like. The pixel circuit may be connected to a scan line SL, a data line DL, and a driving voltage line PL, which crosses the scan line SL. The scan line SL may extend in an x-axis direction, and the data line DL and the driving voltage line PL may extend in a y-axis direction.

Due to driving of the pixel circuit, the pixels P may emit light. The display area DA may provide an image according to light emitted from the plurality of pixels P. As described above, each of the plurality of pixels P in this specification may be defined as an emission area configured to emit red light, green light, blue light, and/or white light.

The peripheral area PA is an area in which the plurality of pixels P are not arranged and no image may be provided. An internal driving circuit, a power supply line, a printed circuit board including a driving circuit, and/or a terminal portion connected to a driver integrated circuit (IC) may be arranged in the peripheral area PA so as to drive the plurality of pixels P.

The display device 1 may be an electronic device including a display panel. The electronic device may be a vehicle display device including a cluster, a center information display (CID), and/or a passenger display, a wearable electronic device that may be worn on a part of a user's body, a medical electronic device, a robot, an electronic device for advertising or display, and/or an educational electronic device.

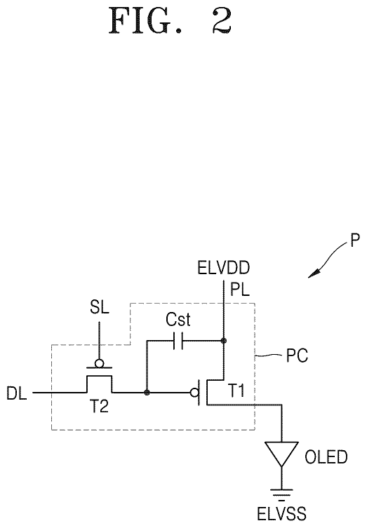

FIG. 2 is an equivalent circuit diagram illustrating a display element provided in one pixel P of a display device and a pixel circuit PC connected the pixel, according to one or more embodiments of the present disclosure. Each of the plurality of pixels P may have a configuration the same as or similar to that described below with reference to FIG. 2.

Referring to FIG. 2, the display element, i.e., an organic light-emitting diode OLED, is connected to the pixel circuit PC. The pixel circuit PC may include a first thin-film transistor T1, a second thin-film transistor T2, and a storage capacitor Cst. For example, the organic light-emitting diode OLED may be to emit red light, green light, or blue light, or may be to emit red light, green light, blue light, or white light.

The second thin-film transistor T2 is a switching thin-film transistor. The second thin-film transistor T2 may be connected to the scan line SL and the data line DL, and may be configured to transmit, to the first thin-film transistor T1, a data voltage input from the data line DL according to a switching voltage input from the scan line SL. The storage capacitor Cst may be connected to the second thin-film transistor T2 and the driving voltage line PL, and may be configured to store charges corresponding to a difference between a voltage received from the second thin-film transistor T2 and a first power supply voltage ELVDD supplied to the driving voltage line PL.

The first thin-film transistor T1 may be a driving thin-film transistor. The first thin-film transistor T1 may be connected to the driving voltage line PL and the storage capacitor Cst, and may be configured to control a driving current flowing from the driving voltage line PL to the organic light-emitting diode OLED in response to charges stored in the storage capacitor Cst. The organic light-emitting diode OLED may be to emit light having a certain luminance according to the driving current. An opposite electrode (e.g., a cathode) of the organic light-emitting diode OLED may be configured to receive a second power supply voltage ELVSS.

FIG. 2 illustrates that the pixel circuit PC includes two thin-film transistors and one storage capacitor, but in one or more embodiments, the number of thin-film transistors or the number of storage capacitors may be variously changed according to the design of the pixel circuit PC.

FIG. 3 is a cross-sectional view schematically illustrating the display device 1 according to one or more embodiments of the present disclosure.

For example, FIG. 3 is a cross-sectional view of the display device 1 taken along the line III-III′ of FIG. 1, according to one or more embodiments of the present disclosure.

Referring to FIG. 3, the display device 1 may include a display panel 2, a first adhesive layer 3, and a cover glass 4. The cover glass 4 may be arranged on the display panel 2. The cover glass 4 may entirely cover (e.g., may cover the entirety of) the display panel 2. The first adhesive layer 3 may be arranged between the display panel 2 and the cover glass 4. For example, the first adhesive layer 3 may be arranged on the display panel 2, and the cover glass 4 may be arranged on the first adhesive layer 3.

The display panel 2 may include a substrate 100, a display layer 200, an encapsulation layer 300, a touch layer 400, and an optical layer 500.

The substrate 100 may include glass or polymer resin. In one or more embodiments, the polymer resin may include polyethersulfone, polyacrylate, polyether imide, polyethylene naphthalate, polyethylene terephthalate, polyphenylene sulfide, polyarylate, polyimide, polycarbonate, or cellulose acetate propionate. The substrate 100 including the polymer resin may have flexible, rollable or bendable properties. The substrate 100 may have a single-layer structure or a multi-layer structure. When the substrate 100 has a multi-layer structure, the substrate 100 may include a layer including a polymer resin and a layer including an inorganic insulating material.

The display layer 200 may be arranged on the substrate 100. The display layer 200 may include a light-emitting diode as a display element, a thin-film transistor electrically connected to the light-emitting diode, and insulating layers arranged therebetween. The substrate 100 of the display device 1 may define the display area DA and the peripheral area PA, and the display layer 200 including the light-emitting diodes as display elements may be in the display area DA, and the peripheral area PA around (e.g., surrounding) the display area DA may not include display elements. For example, the display layer 200, which includes light-emitting diodes as display elements, may be located in the display area DA. The peripheral area PA surrounding the display area DA may not include any display elements.

The encapsulation layer 300 may be arranged on the display layer 200. In one or more embodiments, the display layer 200 may be covered and sealed by the encapsulation layer 300. The encapsulation layer 300 may include at least one inorganic encapsulation layer and at least one organic encapsulation layer.

In one or more embodiments, the display device 1 may include an encapsulation substrate formed of glass, instead of the encapsulation layer 300. The encapsulation substrate may be arranged on the display layer 200, and the display layer 200 may be arranged between the substrate 100 and the encapsulation substrate. A gap may exist between the encapsulation substrate and the display layer 200, and this gap may be filled with a filler.

The touch layer 400 may be arranged on the encapsulation layer 300. The touch layer 400 may detect an external input, such as a touch of an object such as a finger or a stylus pen, so that the display device 1 may obtain coordinate information corresponding to a location of the touch. The touch layer 400 may include touch electrodes and trace lines connected to the touch electrodes. The touch layer 400 may detect an external input by a mutual cap method or a self-cap method.

In one or more embodiments, the touch layer 400 may be formed directly on the encapsulation layer 300. Alternatively, in one or more embodiments, the touch layer 400 may be formed separately and then adhered to the encapsulation layer 300 through an adhesive layer such as an optically clear adhesive.

The optical layer 500 may be arranged on the touch layer 400. The optical layer 500 may include a light shielding layer and/or a color filter. Each color filter may have a color that corresponds to light emitted from the light-emitting elements located beneath the respective color filter.

The cover glass 4 may be arranged on the optical layer 500. The cover glass 4 may include a glass portion 41, a first ink layer 42, and a second ink layer 43. The glass portion 41 may include a transparent material. For example, the glass portion 41 may include a glass material. For example, the glass portion 41 may include at least one of polyimide, polycarbonate, polyethyleneterephthalate, and/or polymethyl methacrylate. A surface of the glass portion 41 facing (e.g., opposite to) the substrate 100 is referred to as a first glass surface 41S.

The first ink layer 42 may be arranged on the first glass surface 41S of the glass portion 41 so as to overlap the peripheral area PA. The first ink layer 42 may be arranged to protrude from the glass portion 41 toward the substrate 100. The first ink layer 42 may not overlap the display area DA of the glass portion 41. For example, the first ink layer 42 may expose the display area DA of the glass portion 41. A surface of the first ink layer 42, which faces the substrate 100, is referred to as a first ink surface 42S.

The first ink layer 42 may include a base resin and a shielding ink. The base resin of the first ink layer 42 may include at least one of polyurethane resin, phenol resin, urea resin, epoxy resin, polyester resin, polyimide resin, and/or melamine resin. For example, the base resin of the first ink layer 42 may include one of polyurethane resin, phenol resin, urea resin, epoxy resin, polyester resin, polyimide resin, and/or melamine resin, or may be a (e.g., any suitable) mixture of two or more materials selected therefrom.

The shielding ink of the first ink layer 42 may include carbon black particles. However, the present disclosure is not limited thereto, and the shielding ink of the first ink layer 42 may include one or more suitable pigments, dyes, or mixtures thereof other than carbon black particles. The internal components of the display device 1 may be prevented or reduced from being seen from the outside by the shielding ink of the first ink layer 42.

The second ink layer 43 may be arranged on the first ink surface 42S of the first ink layer 42 so as to overlap the peripheral area PA. The second ink layer 43 may be arranged to protrude from the first ink layer 42 toward the substrate 100. The second ink layer 43 may not overlap the display area DA of the glass portion 41. For example, the second ink layer 43 may expose the display area DA of the glass portion 41.

The second ink layer 43 may improve adhesion to the first adhesive layer 3. For example, the second ink layer 43 may include the same material as the first ink layer 42. For example, the second ink layer 43 may include a base resin and a shielding ink. The base resin of the second ink layer 43 may include at least one of polyurethane resin, phenol resin, urea resin, epoxy resin, polyester resin, polyimide resin, and/or melamine resin. For example, the shielding ink of the second ink layer 43 may include carbon black particles.

However, this is an example, and a material included in the second ink layer 43 is not limited thereto. The second ink layer 43 may include one or more suitable materials, for example, depending on a material included in the first adhesive layer 3.

The first adhesive layer 3 may fix the display panel 2 and the cover glass 4. The display panel 2 and the cover glass 4 may be attached to each other by the first adhesive layer 3. For example, the first adhesive layer 3 may include an optically clear adhesive.

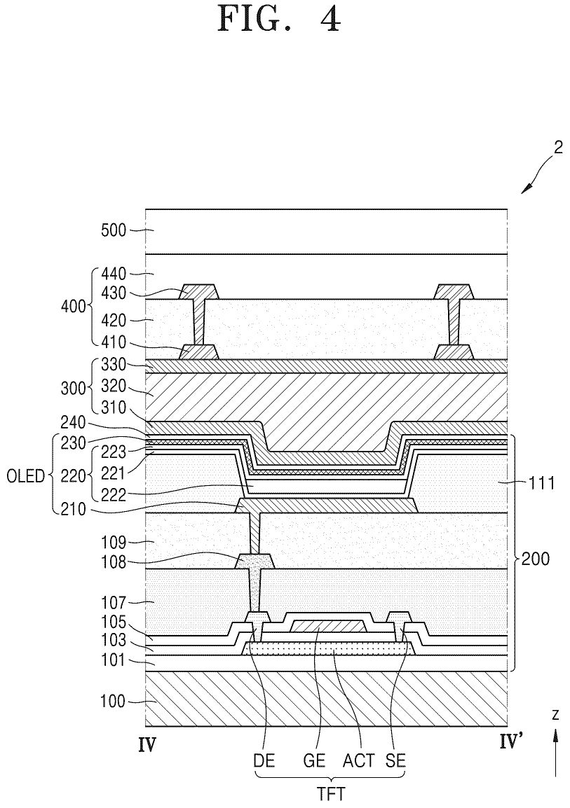

FIG. 4 is a cross-sectional view schematically illustrating a portion of the display panel 2 according to one or more embodiments of the present disclosure.

For example, FIG. 4 is a cross-sectional view of the display device 1 taken along the line IV-IV′ of FIG. 1, according to one or more embodiments of the present disclosure. For example, FIG. 4 may be a cross-sectional view showing a portion of the display panel 2 in the display area DA. The remaining portions in the display area DA of the display panel 2 may have a configuration the same as or similar to that described below with reference to FIG. 4.

Referring to FIG. 4, an organic light-emitting diode OLED may be arranged as a display element on the substrate 100. The organic light-emitting diode OLED may be electrically connected to a thin-film transistor TFT.

The display layer 200 may be arranged on the substrate 100. The display layer 200 may include a buffer layer 101, a gate insulating layer 103, an interlayer insulating layer 105, the thin-film transistor TFT, a first organic insulating layer 107, a contact metal 108, a second organic insulating layer 109, a pixel-defining layer 111, the organic light-emitting diode OLED, and a capping layer 240.

The buffer layer 101 may be arranged on the substrate 100. The buffer layer 101 may serve to flatten and protect an upper surface of the substrate 100. The buffer layer 101 may include at least one inorganic insulating material such as silicon oxide (SiOₓ, where, e.g., 0<x≤2), silicon nitride (SiₓN_{y}, where, e.g., 0<x≤3 and 0<y≤4), and/or silicon oxynitride (SiON). The buffer layer 101 may have a single-layer structure or a multi-layer structure.

The thin-film transistor TFT may be arranged on the buffer layer 101. The thin-film transistor TFT may include an active layer ACT, a gate electrode GE, a source electrode SE, and a drain electrode DE. The thin-film transistor TFT may be connected to the organic light-emitting diode OLED to drive the organic light-emitting diode OLED.

The active layer ACT may be arranged on the buffer layer 101 and may include a drain area overlapping the drain electrode DE, a source area overlapping the source electrode SE, and a channel area arranged between the drain area and the source area. The drain area and the source area may be areas doped with impurities (i.e., dopants).

The gate insulating layer 103 may be arranged on the active layer ACT. The gate insulating layer 103 may include an inorganic insulating material. For example, the gate insulating layer 103 may include at least one inorganic insulating material, such as silicon oxide (SiOₓ), silicon nitride (SiₓN_{y}), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂). The gate insulating layer 103 may have a single-layer structure or a multi-layer structure.

The gate electrode GE may be arranged on the gate insulating layer 103. The gate electrode GE may overlap the active layer ACT. For example, the gate electrode GE may overlap the channel area of the active layer ACT. The gate electrode GE may include at least one conductive material, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). The gate electrode GE may have a single-layer structure or a multi-layer structure.

The interlayer insulating layer 105 may be arranged on the gate electrode GE. The interlayer insulating layer 105 may include an inorganic insulating material. For example, the interlayer insulating layer 105 may include at least one inorganic insulating material such as silicon oxide (SiOₓ), silicon nitride (SiₓN_{y}), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂). The interlayer insulating layer 105 may have a single-layer structure or a multi-layer structure.

The gate insulating layer 103 and the interlayer insulating layer 105 may include a contact hole overlapping the source area of the active layer ACT and a contact hole overlapping the drain area. The source electrode SE and the drain electrode DE may be arranged on the interlayer insulating layer 105. The source electrode SE may be arranged to overlap the source area of the active layer ACT, and the drain electrode DE may be arranged to overlap the drain area of the active layer ACT. The source electrode SE and the drain electrode DE may be connected to the active layer ACT through contact holes formed in the gate insulating layer 103 and the interlayer insulating layer 105, respectively. For example, the source electrode SE may be connected to the source area of the active layer ACT, and the drain electrode DE may be connected to the drain area of the active layer ACT.

The first organic insulating layer 107 and the second organic insulating layer 109 may be sequentially arranged on the interlayer insulating layer 105. The first organic insulating layer 107 and the second organic insulating layer 109 may each include an opening overlapping the drain electrode DE. The contact metal 108 may be arranged on the first organic insulating layer 107. The contact metal 108 may be connected to the drain electrode DE through an opening formed in the first organic insulating layer 107. The opening of the second organic insulating layer 109 overlapping the drain electrode DE may overlap the contact metal 108.

The contact metal 108 may include aluminum (Al), copper (Cu), and/or titanium (Ti). The contact metal 108 may have a single-layer structure or a multi-layer structure.

The first organic insulating layer 107 and the second organic insulating layer 109 may each include general-purpose polymers such as benzocyclobutene, polyimide, hexamethyldisiloxane, polymethylmethacrylate, or polystyrene, polymer derivatives having phenolic groups, acrylic polymers, imide polymers, aryl ether polymers, amide polymers, fluorine polymers, p-xylene polymers, or vinyl alcohol polymers. The first organic insulating layer 107 and the second organic insulating layer 109 may each have a single-layer structure or a multi-layer structure.

The pixel electrode 210 may be arranged on the second organic insulating layer 109. The pixel electrode 210 may be connected to the contact metal 108 through the opening of the second organic insulating layer 109. Accordingly, the pixel electrode 210 is connected to the thin-film transistor TFT through the contact metal 108 and the drain electrode DE and may receive a voltage.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. The composition and material of the pixel electrode 210 are not limited thereto and one or more suitable modifications are possible.

The pixel-defining layer 111 may be arranged on the second organic insulating layer 109. The pixel-defining layer 111 may cover an edge of the pixel electrode 210. For example, the pixel-defining layer 111 may be opened (e.g., have an opening) to expose a central portion of the pixel electrode 210. The size and shape of a light-emitting area of the organic light-emitting diode OLED may be determined by size and shape of the opening of the pixel-defining layer 111.

The intermediate layer 220 may be arranged on the pixel electrode 210. The intermediate layer 220 may include a first common layer 221 and a second common layer 223, which are arranged on the pixel-defining layer (e.g., on an entirety of the pixel-defining layer) 111 and within the opening of the pixel-defining layer 111, and may include an emission layer 222 arranged within the opening of the pixel-defining layer 111. In one or more embodiments, the first common layer 221 may be arranged on the pixel-defining layer 111 and within the opening of the pixel-defining layer 111, the emission layer 222 may be arranged within the opening of the pixel-defining layer 111 on the first common layer 221, and the second common layer 223 may be arranged on the first common layer 221 in an area corresponding to the pixel-defining layer and may cover the emission layer 222 in the opening of the pixel-defining layer 111. For example, the emission layer 222 is arranged within the opening of the pixel-defining layer 111 and may be arranged between the first common layer 221 and the second common layer 223. For example, the intermediate layer 220 is arranged on the pixel electrode 210 and includes a first common layer 221, an emission layer 222, and a second common layer 223. The first common layer 221 is positioned on and within the opening of the pixel-defining layer 111. The emission layer 222 is located within the opening of the pixel-defining layer 111, on top of the first common layer 221. The second common layer 223 is placed on the first common layer 221, covering the emission layer 222 within the opening of the pixel-defining layer 111. The emission layer 222 is situated between the first and second common layers within the opening of the pixel-defining layer 111.

The emission layer 222 may include an organic emission layer including a low-molecular-weight or high-molecular-weight material. The first common layer 221 may include an electron transport layer and/or an electron injection layer. The second common layer 223 may include a hole transport layer and/or a hole injection layer. In one or more embodiments, the first common layer 221 or the second common layer 223 may not be provided. In one or more embodiments, the positions of the first common layer 221 and the second common layer 223 may be switched.

An opposite electrode 230 may be arranged on the intermediate layer 220. For example, the opposite electrode 230 may be arranged on the second common layer 223. The opposite electrode 230 may entirely cover (e.g., may cover an entirety of) the intermediate layer 220. The opposite electrode 230 may include a conductive material having a low work function. For example, the opposite electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In one or more embodiments, the opposite electrode 230 may further include a layer such as ITO, IZO, ZnO or In₂O₃ on the (semi-)transparent layer including the aforementioned material(s).

The capping layer 240 may be arranged on the opposite electrode 230. The capping layer 240 may have a lower refractive index than the opposite electrode 230, and may serve to improve optical efficiency by reducing the proportion of light generated in the intermediate layer 220 and not emitted to the outside due to (total) reflection.

The capping layer 240 may be an organic capping layer including an organic material, an inorganic capping layer including an inorganic material, or a composite capping layer including an organic material and an inorganic material. For example, the capping layer 240 may include a carbocyclic compound, a heterocyclic compound, an amine group-including compound, a porphine derivative, a phthalocyanine derivative, a naphthalocyanine derivative, an alkali metal complex, an alkaline earth metal complex, or a (e.g., any suitable) combination thereof. In one or more embodiments, the capping layer 240 may include an inorganic material such as zinc oxide (ZnO), titanium oxide (TiOₓ, where, e.g., 0<x≤2), zirconium oxide (ZrOₓ, where, e.g., 0<x≤2), nitrogen oxide (NO), niobium oxide (NbOₓ, where, e.g., 0<x≤2), tantalum oxide (TaₓO_{y}, where, e.g., 0<x≤2 and 0<y≤5), tin oxide (SnOₓ, where, e.g., 0<x≤2), nickel oxide (NiOₓ, where, e.g., 0<x≤1), indium nitride (InN), or gallium nitride (GaN). However, the material included in the capping layer 240 is not limited thereto and may be any (suitable) material.

The encapsulation layer 300 may be arranged on the capping layer 240. The encapsulation layer 300 may include at least one inorganic layer and at least one organic layer. In one or more embodiments, the encapsulation layer 300 may include a first inorganic encapsulation layer 310, a second inorganic encapsulation layer 330, and an organic encapsulation layer 320 between the first inorganic encapsulation layer 310 and the second inorganic encapsulation layer 330. The first inorganic encapsulation layer 310 and/or the second inorganic encapsulation layer 330 may include one or more inorganic insulators, such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The organic encapsulation layer 320 may include a polymer-based material. The polymer-based material may include a silicone resin, acrylic resin, epoxy resin, polyimide, and/or polyethylene.

The touch layer 400 may be arranged on the encapsulation layer 300. The touch layer 400 may include a first touch electrode 410, a first touch insulating layer 420, a second touch electrode 430, and a second touch insulating layer 440. The first touch electrode 410 may be arranged on the encapsulation layer 300. For example, the first touch electrode 410 may be arranged on the second inorganic encapsulation layer 330. The first touch insulating layer 420, the second touch electrode 430, and the second touch insulating layer 440 may be sequentially arranged on the first touch electrode 410. The first touch insulating layer 420 and/or the second touch insulating layer 440 may include an inorganic insulating material and/or an organic insulating material. The first touch electrode 410 and the second touch electrode 430 may not overlap the light-emitting area of the organic light-emitting diode OLED. For example, the first touch electrode 410 and the second touch electrode 430 may not overlap the pixel electrode 210 or the opening of the pixel-defining layer 111.

In one or more embodiments, an insulating film may be additionally arranged between the first touch electrode 410 and the second inorganic encapsulation layer 330. The above insulating film may include at least one inorganic insulating material selected from among silicon oxide (SiOₓ), silicon nitride (SiNₓ), and silicon oxynitride (SiON).

The optical layer 500 may be arranged on the touch layer 400. For example, the optical layer 500 may be arranged on the second touch insulating layer 440. The optical layer 500 may include a light shielding layer and/or a color filter.

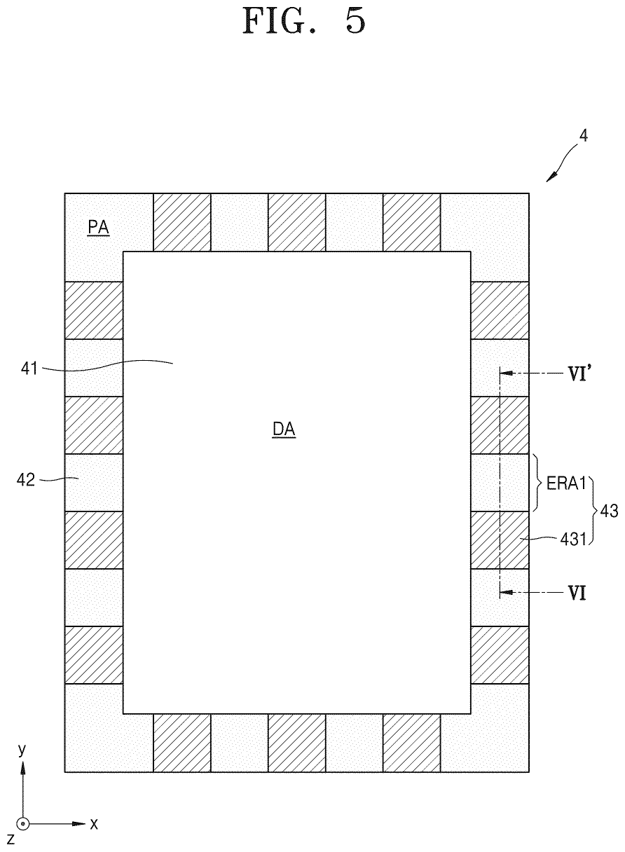

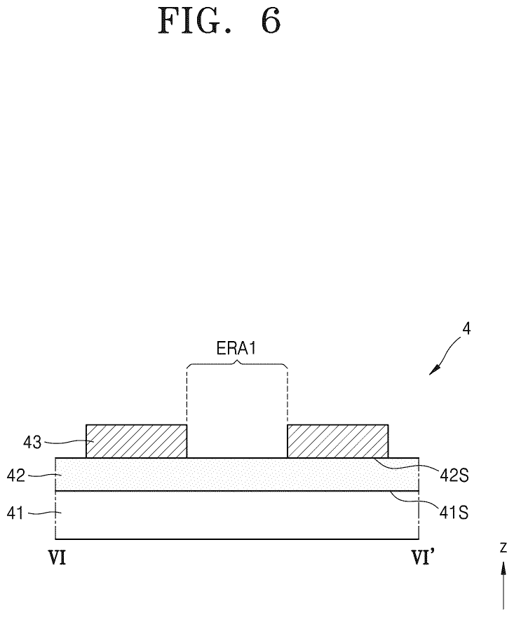

FIG. 5 is a plan (e.g., bottom-up) view schematically illustrating the cover glass 4 according to one or more embodiments of the present disclosure. FIG. 6 is a cross-sectional view schematically illustrating the cover glass 4 according to one or more embodiments of the present disclosure.

For example, FIG. 6 is a cross-sectional view of the cover glass 4 taken along the line VI-VI′ of FIG. 5, according to one or more embodiments of the present disclosure.

Referring to FIG. 3, FIG. 5, and FIG. 6, the cover glass 4 may include the glass portion 41, the first ink layer 42 and the second ink layer 43.

The first ink layer 42 may be arranged on the first glass surface 41S of the glass portion 41 so as to overlap the peripheral area PA. The first ink layer 42 may be arranged to protrude from the glass portion 41 toward the substrate 100. The first ink layer 42 may not overlap the display area DA of the glass portion 41. For example, the first ink layer 42 may expose the display area DA of the glass portion 41. The thickness of the first ink layer 42 may be constant. The first ink surface 42S of the first ink layer 42 may be flat.

The second ink layer 43 may be arranged on the first ink surface 42S of the first ink layer 42 so as to overlap the peripheral area PA. The second ink layer 43 may be arranged to protrude from the first ink layer 42 toward the substrate 100. The second ink layer 43 may not overlap the display area DA of the glass portion 41. For example, the second ink layer 43 may expose the display area DA of the glass portion 41.

The second ink layer 43 may include an ink portion 431 including a shielding ink and a plurality of first areas ERA1 (e.g., a plurality of openings between the ink portions 431) exposing the first ink layer 42 from the ink portion 431. The ink portion 431 may form an outer appearance of the second ink layer 43. The thickness of the ink portion 431 may be the same along the perimeter of the first glass surface 41S.

The ink portion 431 may be provided in plurality, and the plurality of ink portions 431 are spaced and/or apart (e.g., spaced apart or separated) from each other with the plurality of first areas ERA1 arranged therebetween. The thickness of the plurality of ink portions 431 may be the same as the thickness of the plurality of first areas ERA1 (e.g., may be the same as the depth of the openings between the ink portions 431). The plurality of ink portions 431 and the plurality of first areas ERA1 may be arranged alternately. In a cross-sectional view, the first ink layer 42 and the second ink layer 43 may be provided as an uneven structure.

The plurality of ink portions 431 may be arranged along the perimeter of the peripheral area PA. For example, the plurality of ink portions 431 may be arranged with each other at equal intervals. The width of the plurality of ink portions 431 may be the same as the width of the first ink layer 42 (e.g., where the width of the plurality of ink portions 431 and the width of the first ink layer 42 may be along the x-axis direction and/or the y-axis direction). The plurality of first areas ERA1 may be arranged along the perimeter of the peripheral area PA. For example, the plurality of first areas ERA1 may be arranged with each other at equal intervals. The width of the plurality of first areas ERA1 may be the same as the width of the first ink layer 42 (e.g., where the width of the plurality of first areas ERA1 and the width of the first ink layer 42 may be along the x-axis direction and/or the y-axis direction).

As illustrated in FIG. 5, a planar shape (e.g., the shape when viewed on a plane, such as in a plan view (e.g., bottom-up view)) of at least one of the plurality of ink portions 431 may be a rectangle (e.g., a square). Additionally, a planar shape of at least one of the plurality of first areas ERA1 may be a rectangle (e.g., a square).

However, this is an example, and the shape of the second ink layer 43 is not limited thereto.

At least a portion of the first adhesive layer 3 (see, e.g., FIG. 3) may be arranged in at least one of the plurality of first areas ERA1. The first adhesive layer 3 may be in contact with at least one of the plurality of ink portions 431 and the first ink layer 42. Due to the uneven structure of the first ink layer 42 and the second ink layer 43 in combination, a contact area between the first adhesive layer 3 and the cover glass 4 may be increased. Accordingly, adhesive strength between the cover glass 4 and the first adhesive layer 3 may be improved. For example, because the adhesive layer 3 is positioned in the plurality of first areas ERA1 in the peripheral area PA between the plurality of ink portions 431, adhesion between the cover glass 4 and the adhesive layer 3, and hence between the cover glass 4 and the substrate 100, may be improved. For example, a portion of the first adhesive layer 3 is arranged in the first areas ERA1 and contacts the ink portions 431 and the first ink layer 42. The uneven structure of the combined first and second ink layers increases the contact area between the adhesive layer 3 and the cover glass 4, improving adhesive strength. This positioning in the peripheral area PA enhances adhesion between the cover glass 4, the adhesive layer 3, and the substrate 100.

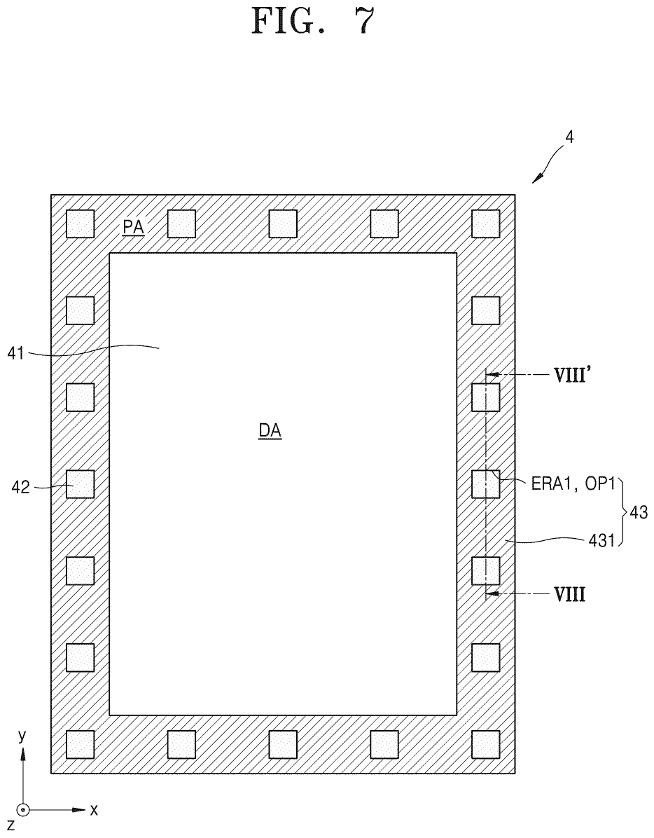

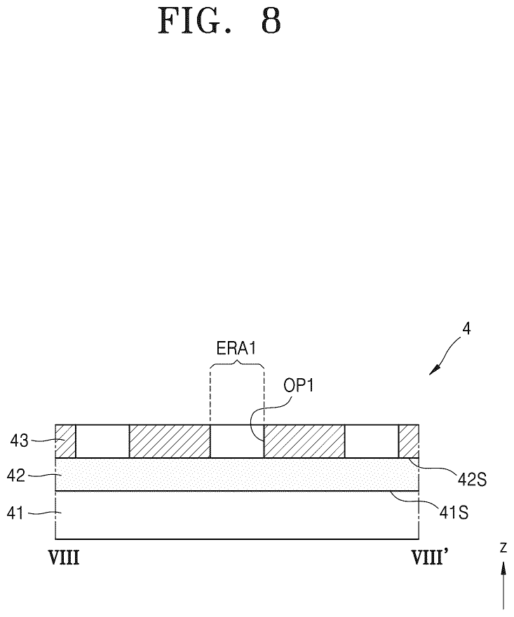

FIG. 7 is a plan (e.g., bottom-up) view schematically illustrating the cover glass 4 according to one or more embodiments of the present disclosure. FIG. 8 is a cross-sectional view schematically illustrating the cover glass 4 according to one or more embodiments of the present disclosure.

For example, FIG. 8 is a cross-sectional view of the cover glass 4 taken along the line VIII-VIII′ of FIG. 7, according to one or more embodiments of the present disclosure. In FIGS. 7 and 8, the same reference numerals as those in FIGS. 5 and 6 refer to the same elements, and thus, redundant descriptions thereof may not be provided.

Referring to FIG. 3, FIG. 7 and FIG. 8, the cover glass 4 may include the glass portion 41, the first ink layer 42 and the second ink layer 43.

The first ink layer 42 may be arranged on the first glass surface 41S of the glass portion 41 so as to overlap the peripheral area PA. The second ink layer 43 may be arranged on the first ink surface 42S of the first ink layer 42 so as to overlap the peripheral area PA.

The second ink layer 43 may include the ink portion 431 including a shielding ink and the plurality of first areas ERA1 exposing the first ink layer 42 from the ink portion 431. The ink portion 431 may form an outer appearance of the second ink layer 43.

The ink portion 431 may be provided as one piece (e.g., a single, unitary piece). The ink portion 431 may extend along the peripheral area PA. The shape of the ink portion 431 in a plan view (e.g., bottom-up view) may include a frame shape. The thickness of the ink portion 431 may be the same along the perimeter of the first glass surface 41S.

The plurality of first areas ERA1 may include a plurality of first openings OP1 that are spaced and/or apart (e.g., spaced apart or separated) from each other and that expose the first ink layer 42 from the ink portion 431. The plurality of first openings OP1 may be arranged along the perimeter of the peripheral area PA. For example, the plurality of first openings OP1 may be arranged with each other at equal intervals. The plurality of first openings OP1 may be arranged with each other in a straight line along a first direction (e.g., x-axis direction) and/or a second direction (e.g., y-axis direction). The width of the plurality of first openings OP1 may be narrower than the width of the first ink layer 42 (e.g., where the width of the plurality of first openings OP1 and the width of the first ink layer 42 may be along the x-axis direction and/or the y-axis direction). For example, the first areas ERA1 include multiple first openings OP1 that are spaced apart and expose the first ink layer 42 from the ink portion 431. These openings are arranged with each other along the perimeter of the peripheral area PA at equal intervals. The openings may be aligned in a straight line along the x-axis or y-axis direction. The width of each of the openings is narrower than the width of the first ink layer 42.

As illustrated in FIG. 7, the planar shape of at least one of the plurality of first openings OP1 may be a rectangle (e.g., a square). However, this is an example, and the shape of the second ink layer 43 is not limited thereto.

At least a portion of the first adhesive layer 3 may be arranged in at least one of the plurality of first openings OP1. At least a portion of the first adhesive layer 3 may be accommodated in at least one of the plurality of first openings OP1. The first adhesive layer 3 may be in contact with at least one of the plurality of ink portions 431 and the first ink layer 42. In this structure, a contact area between the first adhesive layer 3 and the cover glass 4 may be increased. Accordingly, the adhesive strength between the cover glass 4 and the first adhesive layer 3 may be improved.

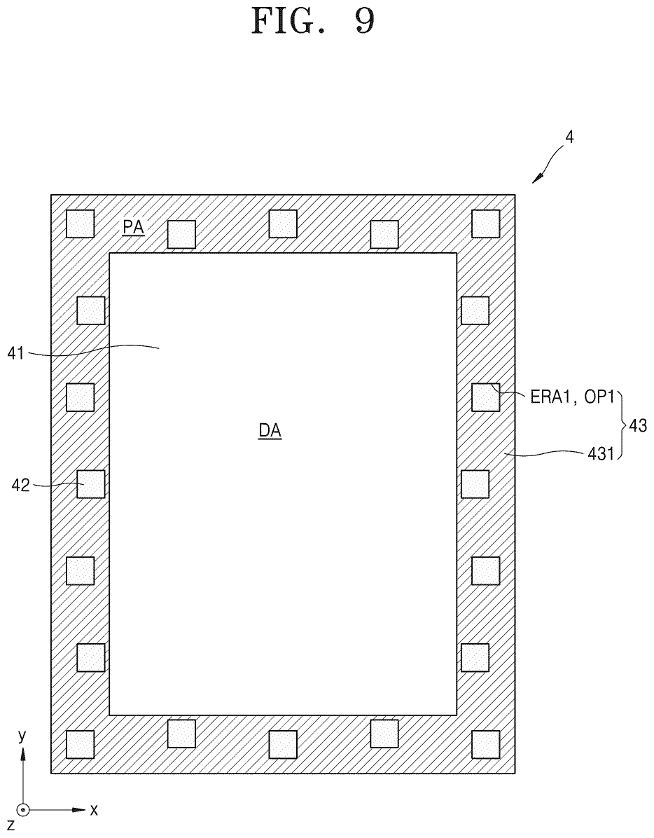

FIG. 9 is a plan (e.g., bottom-up) view schematically illustrating the cover glass 4 according to one or more embodiments of the present disclosure.

In FIG. 9, the same reference numerals as those in FIGS. 5 and 6 refer to the same elements, and thus, redundant descriptions thereof may not be provided.

Referring to FIG. 3 and FIG. 9, the cover glass 4 may include the glass portion 41, the first ink layer 42, and the second ink layer 43.

The second ink layer 43 may include the ink portion 431 including a shielding ink, and may include the plurality of first areas ERA1 exposing the first ink layer 42 from the ink portion 431. The ink portion 431 may form the outer appearance of the second ink layer 43.

The ink portion 431 may be provided as one piece. The ink portion 431 may extend along the peripheral area PA. The shape of the ink portion 431 in a plan (or bottom) view may include a frame shape.

The plurality of first areas ERA1 may include the plurality of first openings OP1 that are spaced and/or apart (e.g., spaced apart or separated) from each other and that expose the first ink layer 42 from the ink portion 431. The plurality of first openings OP1 may be arranged along the perimeter of the peripheral area PA. The width of the plurality of first openings OP1 may be narrower than the width of the first ink layer 42 (e.g., where the width of the plurality of first openings OP1 and the width of the first ink layer 42 may be along the x-axis direction and/or the y-axis direction). For example, the first areas ERA1 include multiple first openings OP1 that are spaced apart from each other and expose the first ink layer 42 from the ink portion 431. These openings are arranged with each other along the perimeter of the peripheral area PA. The width of each of the openings is narrower than the width of the first ink layer 42.

The plurality of first openings OP1 in a plan (or bottom) view may be arranged in a zigzag pattern. The plurality of first openings OP1 may not be arranged in a straight line. The plurality of first openings OP1 may be arranged at equal intervals. As illustrated in FIG. 9, the planar shape of at least one of the plurality of first openings OP1 may be a rectangle (e.g., a square).

However, this is an example, and the arrangement and shape of the first opening OP1 are not limited thereto. For example, the plurality of first openings OP1 may be arranged at different intervals. In addition, in one or more embodiments, the planar shape of the plurality of first openings OP1 may include a circle and/or a triangle.

According to the above embodiments of the present disclosure, the durability of a display device may be improved.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate having a display area and a peripheral area;
a display layer on the substrate;
a first adhesive layer on the display layer; and
a cover glass on the first adhesive layer;
wherein the cover glass comprises:
a glass portion comprising a transparent material;
a first ink layer on a first glass surface of the glass portion, the first glass surface facing the substrate, and the first ink layer overlapping the peripheral area; and
a second ink layer on a first ink surface of the first ink layer, the first ink surface facing the substrate, and the second ink layer overlapping the peripheral area, and
wherein the second ink layer comprises an ink portion comprising a shielding ink and the second ink layer has a plurality of first areas exposing the first ink layer from the ink portion.

2. The display device of claim 1, wherein at least a portion of the first adhesive layer is in at least one of the plurality of first areas.

3. The display device of claim 2, wherein the first adhesive layer is in contact with each of the first ink layer and the ink portion.

4. The display device of claim 1, wherein the first ink layer has a constant thickness.

5. The display device of claim 1, wherein the ink portion comprises a plurality of ink portions, and the plurality of ink portions are spaced from each other with the plurality of first areas arranged therebetween.

6. The display device of claim 5, wherein the plurality of ink portions are arranged at equal intervals along a perimeter of the peripheral area.

7. The display device of claim 1, wherein
the ink portion is one piece and
the plurality of first areas comprise a plurality of first openings that are spaced from each other and expose the first ink layer from the ink portion.

8. The display device of claim 7, wherein the plurality of first openings are arranged at equal intervals along a perimeter of the peripheral area.

9. The display device of claim 7, wherein the plurality of first openings are arranged in a zigzag pattern in a plan view.

10. The display device of claim 1, wherein at least one of the plurality of first areas has a rectangular shape in a plan view.

11. A cover glass comprising:
a glass portion comprising a transparent material and having a central area and a peripheral area;
a first ink layer on a first glass surface of the glass portion in the peripheral area and exposing the central area of the glass portion; and
a second ink layer on a first ink surface of the first ink layer,
wherein the second ink layer comprises an ink portion comprising a shielding ink and has a plurality of first areas exposing the first ink layer from the ink portion.

12. The cover glass of claim 11, wherein a thickness of the ink portion is the same along a perimeter of the first glass surface.

13. The cover glass of claim 11, wherein the second ink layer comprises a same material as the first ink layer.

14. The cover glass of claim 11, wherein the first ink layer has a constant thickness.

15. The cover glass of claim 11, wherein the ink portion comprises a plurality of ink portions, and
wherein the plurality of ink portions are spaced from each other with the plurality of first areas arranged therebetween.

16. The cover glass of claim 15, wherein the plurality of ink portions are at equal intervals.

17. The cover glass of claim 11, wherein
the ink portion is one piece, and
the plurality of first areas comprise a plurality of first openings that are spaced from each other and expose the first ink layer from the ink portion.

18. The cover glass of claim 17, wherein the plurality of first openings are at equal intervals.

19. The cover glass of claim 17, wherein the plurality of first openings are arranged in a zigzag pattern in a plan view.

20. The cover glass of claim 11, wherein at least one of the plurality of first areas has a rectangular shape in a plan view.

21. An electronic device comprising:
a cover glass comprising:
a glass portion comprising a transparent material and having a central area and a peripheral area;
a first ink layer on a first glass surface of the glass portion in the peripheral area and exposing the central area of the glass portion; and
a second ink layer on a first ink surface of the first ink layer,
wherein the second ink layer comprises an ink portion comprising a shielding ink and has a plurality of first areas exposing the first ink layer from the ink portion.

22. The electronic device of claim 21, wherein the electronic device is a vehicle display device, a wearable electronic device, a medical electronic device, a robot, an electronic device for advertising or display, or an educational electronic device.
